(19) United States
(12) Patent Application Publication
(10) Pub. No.: US 2006/0242537 A1
(43) Pub. Date: Oct. 26, 2006

(54) Error detection in a logic device without performance impact

(76) Inventor: Lich Xuan Dang, Houston, TX (US)

Correspondence Address: TEXAS INSTRUMENTS INCORPORATED, P O BOX 655474, M/S 3999, DALLAS, TX, 75265, US

(21) Appl. No.: 11/093,358

(22) Filed: Mar. 30, 2005

(51) Int. Cl. G11C 29/00

(52) U.S. Cl. 714/763

(57) ABSTRACT

An apparatus and method to perform error detection in a logic device without performance impact. The apparatus includes an Error Detection Device (EDD) coupled to a memory module and a processor. The memory module connects to the processor. As information transfers from the memory module to the processor, the EDD receives the same information and checks the information for errors. The information may be instructions, data, or control sequences. If the EDD does not detect any errors in the information, the processor is allowed to complete execution of the information. If the EDD detects an error in the information transferred from the memory module, an action is sent to the processor before the erroneous information is executed. Because the error checking is done by the EDD at the same time as the transfer of information from the memory module to the processor, the performance of the system is not impacted.

### TECHNICAL FIELD OF THE INVENTION

The present invention generally relates to detection of errors in a logic device. More particularly, the invention relates to a system to detect errors in a memory device. Still more particularly, the invention relates to detection of errors in a memory device that does not impact system performance.

### BACKGROUND OF THE INVENTION

Memory devices store information, which may be data, instructions, or control sequences, for use by a processor of a computer system, mobile phone system, embedded control system, or any other electronic device that uses a processor and a memory device. A memory device is a repetitive group of identical cells, including transistors, capacitors, and resistors, that store electrical representations of either a 1 value or a 0 value. Because of hardware failures, information stored on the memory device may be corrupted during operation of the system. An error in the memory device may be a cell which is stuck at either the representation of the 1 or 0 value and unable to switch between the values. The cells or bits may be organized into groups that may be 8 bits, 16 bits, or 32 bits and so on. A group of bits may be called a word, thus, as an example, a memory system may implement 16 bit words. A processor may request information from the memory device in a single word or groups of words (2 words, 4 words, and so on). If some cells or bits in the memory storing the 1’s or 0's of the word are stuck, as described above, the memory device will send incorrect information to the processor. Thus, in electronic systems, errors in the memory device cannot be tolerated.

Memory systems use error correction and detection codes to detect, and in certain situations, correct errors in the memory device. One type of code is the Hamming code (described in more detail below), which detects a single bit error in a word, two bit errors in a word, and some three bit errors in a word and corrects the single bit errors in the word.

An Error Detection and Correction Unit (EDCU) is a hardware and software system that implements Hamming codes for detection and correction of errors in words in a memory device. In current implementations, an EDCU is placed between a processor and a memory device. As mentioned above, the memory device may receive a request from the processor for information such as data or instructions. The information transfers from the memory device to EDCU. The EDCU checks the information for single bit, two bit, and three bit errors before passing the information to the processor. If a single bit error is detected by the EDCU, the information is corrected and sent to the processor. If a double bit error or a triple bit error is detected by EDCU, the processor is alerted that a memory error has occurred. Some two bit and three bit errors can be corrected by EDCU.

Detection and correction of errors by EDCU affects the performance of the electronic device. This is because information from the memory device has to pass through the EDCU before it is received by the processor for use. Consequently, any delay caused by the EDCU may delay the electronic device whenever information is transferred from the memory device to the processor.

Error detection and correction systems using an EDCU may be useful in low performance systems, but the effect of an EDCU in high performance systems is more considerable. As processors increase the rate at which they use information, there is a continuing need to detect and correct memory errors with minimum effect on performance. Thus, there is an ongoing need to use memory detection and correction technology with computer systems, mobile telephones, embedded controllers, and other electronic devices to detect and correct memory errors without reducing the performance of the electronic device.

### SUMMARY OF THE INVENTION

The problems noted above are solved by an Error Detection Device (EDD) operatively arranged to detect memory errors. The EDD may be coupled to a processor and a memory module. The memory module also couples directly to the processor. The EDD may operate in parallel with the processor. Thus, the memory module sends the same information to the EDD and the processor at the same time. In some embodiments of the invention, the EDD may use a parity check and Hamming codes to check information, which is data, information, or control sequences, from the memory module for errors. If the EDD detects an error in the information sent to the processor, the location of the erroneous information in the memory device (the error address) and the erroneous information (error data) may be stored in the EDD. A user may interface with the EDD and may use the error address and error data to identify problems within the memory device.

Allowing the EDD to operate in parallel with the processor does not delay the processor from receiving information from the memory device. Thus, the EDD does not affect the performance of the memory system and the electronic device. Information received from the memory device may not be completely executed by the processor for several clock cycles. This delay depends on the level of pipelining in the processor and allows the EDD to inform the processor before the processor uses the erroneous information if an error has been detected in the information transmitted from the memory device.

In one embodiment of the invention, the memory module may consist of a memory interface, a memory device, and a parity module. The memory interface may be coupled to the processor, the memory device, and the parity module. In some embodiments of the invention, the memory device and the parity module may be coupled to the EDD. The EDD may be coupled to the processor through interrupt, reset, and abort means to communicate with the processor if an error is detected by the EDD.

In some embodiments of the invention, an Input/Output Unit (IOU) may be coupled to the EDD, the memory module, and the processor. A peripheral unit may be coupled to the IOU. The peripheral unit may comprise an engine control unit, an automatic transmission control unit, an anti-lock brake system control unit, a tire pressure sensor, an air intake sensor, a revolution sensor, a hydraulic actuator, a fuel injection valve actuator, and a diagnosis indicator. The components of the peripheral unit connect to the IOU.

A method of detecting memory errors is described that includes transmitting information from a memory module to an EDD at the same time the information is transmitted to a processor. The processor may be allowed to begin execution of the information. Further, the EDD may check the information for errors as the processor begins to execute the information. In one embodiment of the invention, the processor may use the information if no errors are detected in the information. The EDD may use a parity check and Hamming codes to detect errors in the information transferred from the memory module. The EDD detects errors in the information from the memory module as the device functions. The EDD may send a memory corruption action to the processor if the EDD detects an error.

If the EDD sends a memory corruption action to the processor, the processor may then call a memory corruption routine. The processor executing the memory corruption routine may activate an indicator signal, switch to a secondary system, halt the system, or begin an error correction process. Furthermore, the EDD may stop the processor from using the information if the EDD detects an error in the information. The EDD may store the addresses of the information containing errors and the erroneous information.

### BRIEF DESCRIPTION OF THE DRAWINGS

FIG. 1 shows an Error Detection and Correction Unit (EDCU) coupled to a memory interface and a memory module with no direct input to the processor from the memory module;

FIG. 2 shows one embodiment of an Error Detection Device (EDD) coupled to a memory module, the memory module capable of sending information directly to the processor;

FIG. 3 shows, in accordance with some embodiments of the invention, a three-stage pipeline implemented in the processor;

FIG. 4 is a flowchart showing operation of the EDD and interaction between the EDD and the processor; and

FIG. 5 shows some embodiments of the system illustrated in FIG. 2 coupled to a peripheral unit via an Input/Output Unit.

### NOTATION AND NOMENCLATURE

Certain terms are used throughout the following description and claims to refer to particular system components and configurations. As one skilled in the art will appreciate, companies may refer to a component by different names. This document does not intend to distinguish between components that differ in name but not function. In the following discussion and in the claims, the terms “including” and “comprising” are used in an open-ended fashion, and thus should be interpreted to mean “including, but not limited to . . .” Also, the term “couple” or “couples” is intended to mean either an indirect or direct electrical connection. Thus, if a first device couples to a second device, that connection may be through a direct electrical connection or though an indirect electrical connection via other devices and connections. Furthermore, the term “information” is intended to refer to any data, instructions, or control sequences that may be communicated between devices. For example, if information is sent between two devices, data, instructions, control sequences, or any combination thereof may be sent between the two devices.

### Detailed Description of Embodiments

In accordance with some embodiments of the invention, in an electronic device, a processor is coupled to a memory module and an Error Detection Device (EDD). The EDD is further coupled to the memory module. The EDD operates in parallel with the processor, and similar information is sent from the memory module to the processor and the EDD at the same time. The EDD detects any errors in the information from the memory module as the device functions.

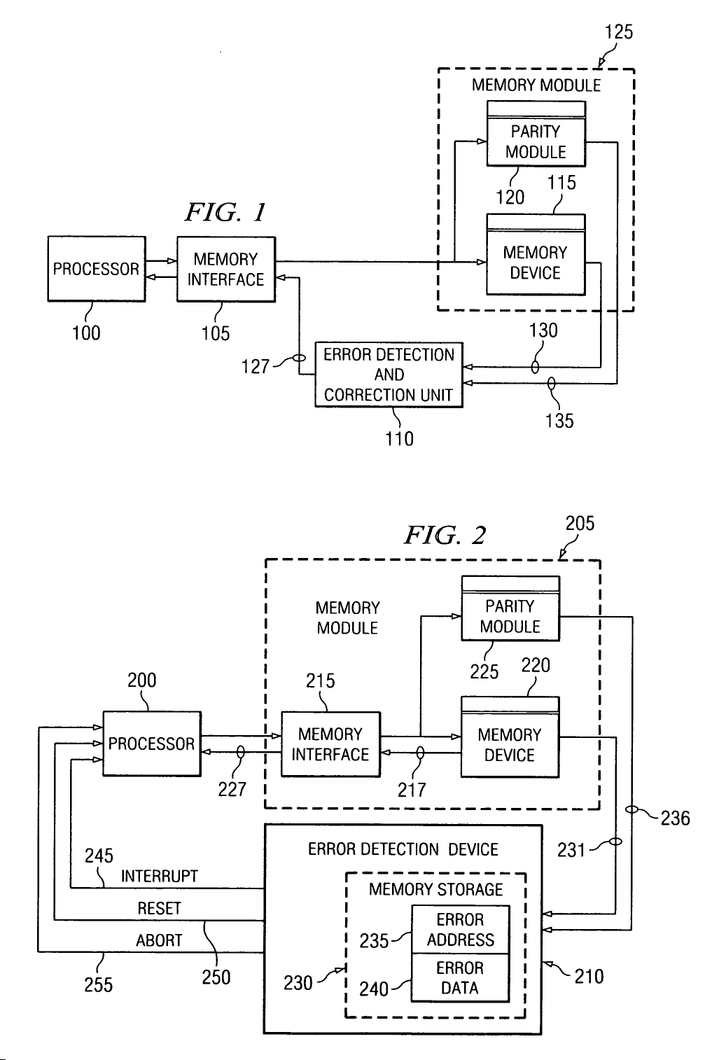

Referring to FIG. 1, an Error Detection and Correction Unit (EDCU) 110 is coupled to a memory interface 105. EDCU 110 outputs information through bus 127 to memory interface 105. EDCU 110 also couples to memory module 125. EDCU 110 receives information from memory module 125 through bus 130 and bus 135. EDCU 110 detects any errors in the information and, if no errors are found, transmits the information through bus 127 to memory interface 105.

Processor 100 may be coupled to memory interface 105. Memory module 125 may include a memory device 115 and a parity module 120. Memory device 115 and parity module 120 is coupled to memory interface 105 as shown in FIG. 1. Memory device 115 and parity module 120 may be further coupled to EDCU 110 through bus 130 and bus 135, respectively.

Processor 100 may be an AMD Athlon 64 FX processor for personal computers, a Texas Instruments TMS470 microcontroller for automobiles, an Intel PXA800EF processor for cellular phones, or any other processing device comprising an arithmetic logic unit, information paths, an information cache, and pipelined execution of instructions. Memory interface 105 may be any device that coordinates the flow of information from processor 100 to memory device 115 and parity module 120. Memory device 115 and parity module 120 may be dynamic random access memory (DRAM), flash erasable programmable read-only memory (FEPROM), erasable programmable read-only memory (EPROM), or any other devices capable of storing and accessing information. The devices shown in FIG. 1 may be combined into a single chip implementation or may be implemented on separate chips on a circuit board and coupled together as shown in FIG. 1.

Processor 100 may read and write information from memory device 115. Before information is written to memory device 115, check bits may be generated using Hamming codes. Hamming code words are generated by appending check bits with raw (uncoded) information bits. The number of check bits is given by the Hamming rule which is a mathematical equation that is a function of the number of bits of information transmitted. Check bits combined with raw information bits are stored as coded information in memory device 115. Descriptions of implementations of Hamming code may be found in Lin et al., “Error Control Coding, Fundamentals and Applications,” Chapter 3 (1982).

Before information is written to memory device 115, the Hamming coded information may be passed through a parity generator device (not shown) and a parity bit may be generated. The parity bit may be stored in a location in parity module 120 corresponding to the address of the Hamming coded information stored in memory device 115. A 32 bit word of raw information, for example, may become a 39 bit word of Hamming coded information when 7 Hamming check bits are added. One parity bit for the coded word of information may be generated and stored in a location in parity module 120 corresponding to the 39 bit word of coded information stored in memory device 115. Generation of Hamming code words and parity bits may occur in memory interface 105, processor 100, or in a separate device or devices coupled between memory device 115 and memory interface 105 or processor 100 (not shown in figure). Further, in some other embodiments of the invention, the parity bit generated by the parity generator device may be stored in memory device 115.

When processor 100 reads information from memory device 115, EDCU 110 retrieves coded information from memory device 115 through bus 130. The coded information stored in memory device 115 is information with check bits inserted at specific locations within the information. EDCU 110 may also retrieve the corresponding parity bit from parity module 120 through bus 135. EDCU 110 may check for errors in the transmitted coded information using Hamming codes and a parity check. If no errors are detected, the check bits may then be removed from the coded information and the information bits may be passed from EDCU 110 through memory interface 105 to processor 100 for execution. In the case of a single bit error, the error may be corrected and the check bits may then be removed from the coded information and the information may be passed from EDCU 110 through memory interface 105 to processor 100 for execution. In the case of a double bit, triple bit, or parity error, the error may be detected, but it may not be possible to determine the specific erroneous bit or bits. Thus, for a double bit, triple bit, or parity error, correction of the specific erroneous bit or bits may not be possible. However, if EDCU 110 detects a double bit, triple bit, or parity error, a predefined memory corruption routine may be executed by processor 100 when EDCU 110 sends an appropriate signal through memory interface 105 to processor 100.

EDCU 110 requires an amount of time to check, correct, and decode the coded information. This time may affect the performance of the system because information transferring from memory device 115 through memory interface 105 to processor 100 needs to first pass through EDCU 110. Consequently, any delay in EDCU 110 may delay the entire system every time information from memory device 115 is sent through memory interface 105 to processor 100. For example, consider a system using a processor 100 that may require 33 nanoseconds (33×10⁻⁹ seconds) to complete the execution of a piece of information such as an instruction. When an EDCU 110 with a 6 nanosecond (ns) delay is placed between memory interface 105 and memory device 115, the time required to complete the execution of the instruction may increase to 39 ns (33 ns+6 ns=39 ns), an increase in execution time of approximately 18%. Now consider a system using a processor that may require 3 ns to complete the execution of the instruction. When an EDCU 110 with a 6 ns delay is placed between memory interface 105 and memory device 115, the time required to complete the execution of the instruction may increase to 9 ns, an increase in execution time of approximately 200%. It follows that more performance reduction may be seen as the time required to complete the execution of an instruction decreases while the delay caused by the EDCU remains the same.

As described above, a system implementing EDCU 110 coupled between processor 100, memory interface 105, and memory device 115 may detect all one bit and two bit errors, some three bit errors, and some parity errors. EDCU 110 may correct all one bit errors. However, the performance of such a system may be degraded by the delay of EDCU 110. As the time required for processors to use information decreases and the delay time caused by EDCU 110 remains the same, the overall performance of the system shown in FIG. 1 is reduced.

Referring to FIG. 2, an Error Detection Device (EDD) 210 is coupled to a memory module 205. A processor 200 is coupled to memory module 205. Memory module 205 sends information to processor 200 through bus 227. Memory module 205 may contain a memory interface 215 coupled to a memory device 220 and a parity module 225. Memory interface 215 may be further coupled to processor 200 through bus 227. Memory device 220 and parity module 225 contained within memory module 205 may send information to EDD 210 through bus 231 and bus 236, respectively. EDD 210 may be coupled to processor 200 by interrupt connection 245 that carries an interrupt signal, reset connection 250 that carries a reset signal, and abort connect 255 that carries an abort signal.

In some embodiments of the invention as shown in FIG. 2, EDD 210 couples to processor 200 through separate interrupt 245, reset 250, and abort 255 lines. In some other embodiments of the invention (not shown in FIG. 2), the interrupt, reset, and abort lines may be incorporated into an information bus that connects processor 200 to EDD 210. In still other embodiments (not shown), a 3-to-1 multiplexer may receive the three separate interrupt, reset, and abort lines from EDD 210 and transmit the signals serially through a single line to processor 200. Other embodiments using any other connection(s) to transmit the interrupt, reset, and abort signals to processor 200 may be implemented.

As described above, information may be encoded using Hamming codes and stored in memory device 220 with a corresponding parity bit stored in parity module 225. When processor 200 requests information from memory device 220, coded information may be transferred from memory device 220 through memory interface 215 to processor 200. The corresponding parity bit may not be transmitted with the coded information to memory interface 215 or processor 200. Hamming check bits may be removed from the coded information and the coded information may be decoded without being checked for errors. This decoding without error checking may take place in memory interface 215, processor 200, memory device 220, or in a separate device (not shown) between memory device 220 and processor 200.

As coded information is sent from memory device 220 to processor 200, identical coded information and the corresponding parity bit is transferred to EDD 210 through bus 231 and bus 236 respectively. EDD 210 may check the coded information from memory device 220 using the Hamming check bits and a parity check. As described above, Hamming codes allow detection of all one bit and two bit errors and some three bit errors. If EDD 210 detects a one bit, two bit, three bit, or parity error, EDD 210 may send a memory corruption action to processor 200 through interrupt connection 245, reset connection 250, abort connection 255, or a combination of the three connections. A memory corruption action indicates to processor 200 that a memory error has been detected by EDD 210. If EDD 210 does not detect an error, it does not send a memory corruption action to processor 200.

If processor 200 receives a memory corruption action from EDD 210, processor 200 may call a memory corruption routine. The processor executing the memory corruption routine may activate a signal to a user indicating a memory error has occurred, switch to a secondary system, halt the system, or begin an error correction process. If EDD 210 detects an error in the information sent to processor 200, the address of the erroneous information in memory device 220 and the erroneous information may be stored in memory storage 230 of EDD 210. The address of the erroneous information may be stored in error address 235, and the erroneous information may be stored in error data 240 of memory storage 230. Memory storage 230 may be accessed by a user to troubleshoot the system shown in FIG. 2. For example, a user may interface with memory storage 230 through a personal computer and examine the addresses of stored information errors in error address 235. The user may use the addresses to identify problem areas within memory device 220 and replace or repair memory device 220.

Because EDD 210 is not in the path 217 between memory device 220 and memory interface 215, there is no delay in the movement of the coded information from memory device 220 through memory interface 215 to processor 200. This is unlike the system in FIG. 1, where EDCU 110 delays the entire system when information is transferred from memory device 115 through EDCU 110 to memory interface 105 and processor 100. In FIG. 2, the system can detect memory errors because EDD 210 checks the coded information from memory device 220 for errors while the coded information transfers from memory device 220 to processor 200. As described above, EDD 210 alerts processor 200 if an error is detected.

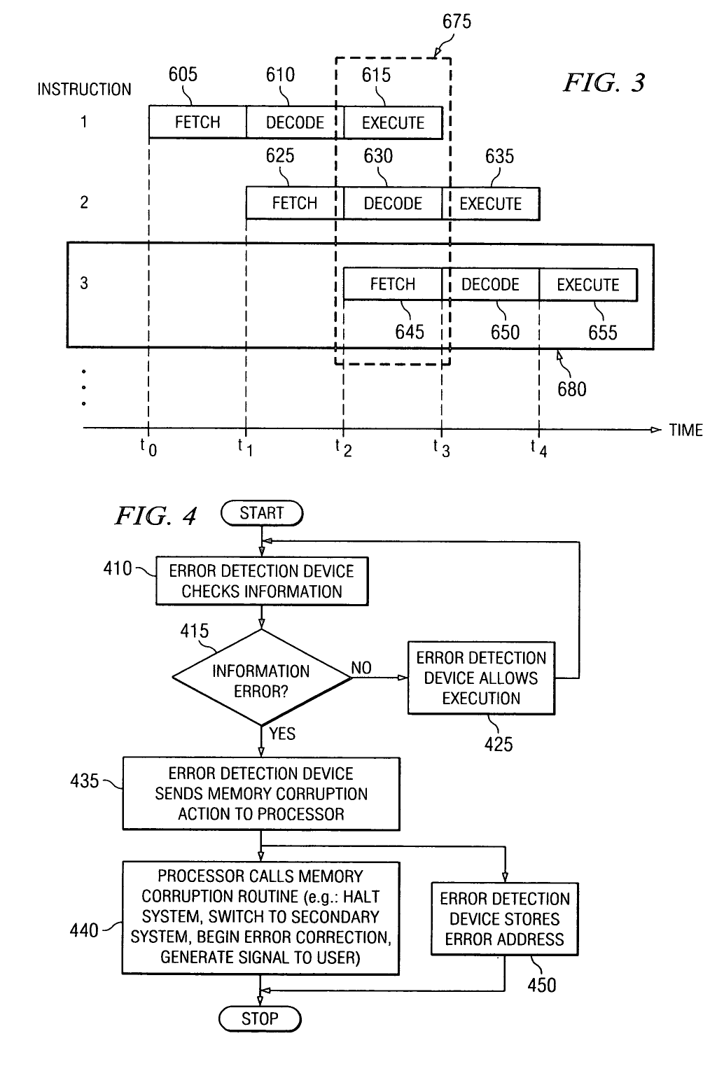

While there may be little to no delay in the movement of coded information from memory device 220 through memory interface 215 to processor 200, there may be a delay associated with error checking in EDD 210. This delay may arise when EDD 210 checks the coded information from memory device 220 using the Hamming code check bits and parity check bit. If an error is detected in EDD 210, this delay may result in interrupt signal 245, reset signal 250, or abort signal 255 signal or a combination of the interrupt, reset, and abort signals from EDD 210 arriving at processor 200 after processor 200 has received the incorrect information from memory device 200. This is acceptable because the incorrect information from memory device 220 may not have executed in the pipeline (described below with reference to FIG. 3) by processor 200 when the interrupt, reset, or abort signal arrive at processor 200.

A pipeline in a processor is a sequence of stages or steps that perform a task similar to the operation of an assembly line in a factory. Each stage of the pipeline operates independently and takes input from the previous stage to produce output that is sent to the next stage of the pipeline. FIG. 3 shows a sample 3-stage pipeline. During fetch stages 605, 625, and 645, information, such as instructions, may be fetched, or received, from a memory device. During decode stages 610, 630, and 650, the instructions fetched from the memory device may be decoded and prepared for execution. During execute stages 615, 635, and 655, instructions fetched from the memory device may be executed. As shown by column 675 starting at a time t₂, instruction 1 is being executed by a processor in the execute stage 615 of the pipeline, instruction 2 is being decoded by the processor in the decode stage 630, and instruction 3 is being fetched from the memory device in the fetch stage 645. Thus, each stage of the pipeline implemented in the processor is filled and operating on an instruction. In some other embodiments of the invention, the processors shown in FIGS. 1, 2, and 5 may implement a pipeline with many more stages than shown in FIG. 3.

For the system shown in FIG. 2, processor 200 may operate with the pipeline shown in FIG. 3. Information, such as data, instructions, and control sequences, may be sent from memory module 205 to processor 200 and from memory module 205 to EDD 210. If an error is detected by EDD 210 and a memory corruption action sent to processor 200 through interrupt 245, reset 250, or abort 255 signal lines, processor 200 may be stopped from using the erroneous information if the memory corruption action is received before the start of the execute stage. For example, referring to FIG. 3, EDD 210 may detect an error in the third instruction 680 sent to processor 200 from memory module 205. EDD 210 may send a memory corruption action to processor 200 through interrupt 245, reset 250, or abort 255 lines. If the memory corruption action sent to processor 200 is received before the start of the execute stage 655 of the third instruction 680 at time t₄, processor 200 calls a memory corruption routine and the third instruction is not used by processor 200. The memory corruption routine may activate a signal indicating that a memory error has occurred, switch to a secondary system, halt the system, or begin an error correction process. As described below, if processor 200 executes the erroneous third instruction 680 because EDD 210 is not able to send the memory corruption action to processor 200 before time t₄, EDD 210 indicates to all external peripherals that an error has occurred and information from processor 200 should not be used.

Referring to FIG. 4, a flowchart is shown detailing operation of the EDD and interaction between the EDD and the processor. The EDD described in FIG. 4 may be EDD 210 shown in FIG. 2. As shown in block 410, EDD 210 checks information transferred from memory module 205 for errors. The information transferred from memory device 220 to EDD 210 is also transferred to processor 200. The corresponding parity bit for the information may be transferred from parity module 225 to EDD 210. EDD 210 checks the information from memory module 205 using the Hamming check bits and the parity check bit and decides if an error is present in the information as shown in block 415. If no error is detected by EDD 210, the EDD allows execution 425 of the information by processor 200 as shown in block 425. EDD 210 then prepares to check the next information requested by processor 200 for errors.

If EDD 210 detects an error, EDD 210 sends a memory corruption action to processor 200 as shown in block 435. This memory corruption action is sent to processor 200 through interrupt, reset, and abort connections as described above.

When processor 200 receives the memory corruption action, processor 200 may call a memory corruption routine as shown in block 440. The memory corruption routine may activate a signal indicating that a memory error has occurred, switch to a secondary system, halt the system, or begin an error correction process. At a similar time, as shown in block 450, the address of the erroneous information in memory device 220 and the erroneous information itself may be stored in EDD 210 in memory storage 230 described above and shown in FIG. 2.

As detailed above, a system implementing EDD 210 coupled to memory module 205 and processor 200 may detect all one bit and two bit errors, some three bit errors, and some parity errors and may alert processor 200 of a memory error. The performance of this system will not be impacted by the delay of the EDD 210. Thus, any delay caused by the EDD in error checking information from the memory module will not cause a bottleneck in the performance of the whole system.

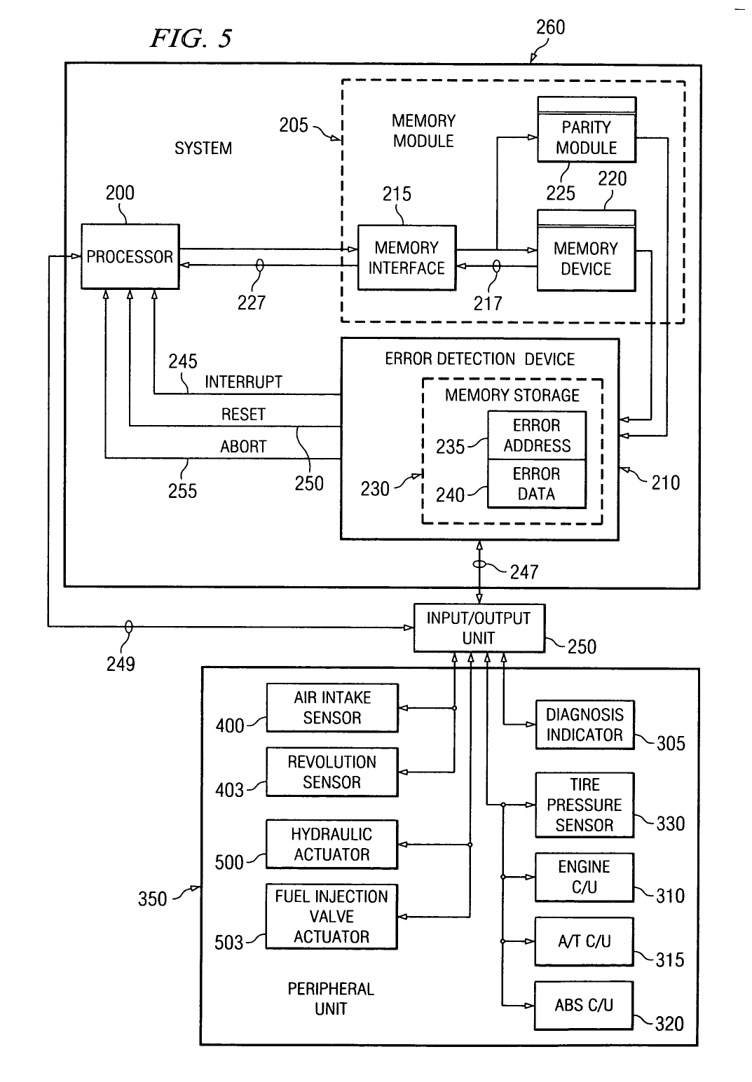

Turning now to FIG. 5, the system illustrated in FIG. 2 is shown coupled to a peripheral module 350. System 260 may be coupled to an Input/Output Unit (IOU) 250 that connects to peripheral unit 350. IOU 250 may be coupled to processor 200 and EDD 210 in system 260. In some embodiments of the invention, IOU 250 may be part of a TMS320C6000 DSP general-purpose device or any device that coordinates the flow of information between system 260 and peripheral unit 350. Peripheral unit 350 may be any device that interacts with system 260 or any devices of system 260 through IOU 250. Further, the devices shown in FIG. 5 may be implemented on a single chip or may be implemented on separate chips. Multiple peripheral units 350 may be coupled to system 260.

Peripheral unit 350 shown in FIG. 5 includes devices of an automobile control system. Peripheral unit 350 may include an engine control unit (engine c/u) 310, an automatic transmission control unit (A/T c/u) 315, an anti-lock braking system control unit (ABS c/u) 320, and a tire pressure sensor 330 coupled to IOU 250. Engine c/u 310 may control ignition timing, fuel injection and the like of an internal combustion engine, automatic transmission c/u 315 may control the changing of gears in a transmission, and ABS c/u 320 may control braking functionality in the automobile. One or more tire pressure sensors 330 may determine tire pressure in the tires of an automobile. Peripheral unit 350 may also include an air intake sensor 400 for detecting the amount of air used by the engine and a revolution sensor 403 for detecting the speed of the engine. The air intake sensor 400 and the revolution sensor 403 both couple to IOU 250. Further, a hydraulic actuator 500, a fuel injection valve actuator 503, and a diagnosis indicator 305 may be coupled to IOU 250. Diagnosis indicator 305 activates a signal to the user if a device complication arises, such as a memory device error or low tire pressure.

Information may pass from peripheral module 350 through IOU 250 to processor 200 through bus 249. The information is processed by processor 200 and stored in memory device 220. Information may also pass from memory device 220 to processor 200, further to IOU 250 through bus 249, and finally to peripheral module 350. As described above, if EDD 210 detects an error in information transferred from memory module 205 to processor 200, EDD 210 may send a memory corruption action to processor 200 to stop the erroneous information from propagating to peripheral unit 350.

Thus, for example, ABS c/u 320, which controls the braking functionality of the automobile, may continuously communicate through IOU 250 with processor 200. If instructions stored in memory device 220 that are executed by processor 200 and affect the operation of ABS c/u 320 contain errors, EDD 210 may detect the errors before the instructions are executed by processor 200. As described above, a memory corruption routine is called by processor 200, which may cause a diagnosis signal to be generated through diagnosis indicator 305. In some embodiments of the invention, the memory corruption routine called by processor 200 may activate a secondary memory system. If EDD 210 is not implemented in the system shown in FIG. 5, erroneous instructions executed by processor 200 may affect operation of ABS c/u 320 causing a vehicle failure that affects passenger safety.

If EDD 210 detects an error in the information stored in memory module 205, EDD 210 may directly alert IOU 250 through connection 247. The alert signaled from EDD 210 to IOU 250 through connection 247 may serve as a secondary error signal. If an erroneous instruction is detected by EDD 210 and a memory corruption action sent to processor 200 through lines 245, 250, or 255 is not received by the processor before it executes the erroneous instruction, the alert signaled by EDD 210 to IOU 250 through connection 247 indicates that the processor has executed an erroneous instruction that should not be propagated to the devices in peripheral module 350. Is some other embodiments of the invention, connection 247 may connect directly to peripheral unit 350, to individual devices of peripheral unit 350 (e.g. engine c/u 310), or to multiple devices of peripheral unit 350 (e.g. ABS c/u 320 and diagnosis indicator 305).

As described above, EDD 210 in FIG. 5 may detect all one bit and two bit errors, some three bit errors, and some parity errors and may alert processor 200, IOU 250, and peripheral unit 350 if an error occurs. The performance of the system shown in FIG. 5 is not impacted by the delay of EDD 210.

While the present invention has been described with respect to a limited number of embodiments, those skilled in the art will appreciate numerous modifications and variations therefrom. It is intended that the appended claims cover all such modifications and variations as fall within the true spirit and scope of this present invention.

What is claimed is:

1. A method of detecting errors in a device, comprising:
transmitting information from a memory module to an Error Detection Device (EDD);
transmitting the information from the memory module to a processor at the same time; and
allowing the processor to begin execution of the information, wherein the EDD checks the information for errors as the processor begins execution of the information.

2. The method of claim 1, wherein the EDD uses Hamming codes to check the information for errors

3. The method of claim 2, wherein the EDD uses a parity check to check the information for errors.

4. The method of claim 1, wherein the EDD does not reduce performance of the device.

5. The method of claim 1, further comprising sending a memory corruption action to the processor if the EDD detects an error.

6. The method of claim 5, wherein the processor completes execution of the information if the EDD detects no errors.

7. The method of claim 5, wherein the processor executes a memory corruption routine when the processor receives the memory corruption action.

8. The method of claim 7, wherein the memory corruption routine comprises at least one of activating an indicator signal, switching to a secondary system, halting the system, and beginning an error correction process.

9. The method of claim 1, further comprising stopping the processor from executing the information if the EDD detects an error in the information.

10. The method of claim 1, further comprising storing the information and an address of the information if the EDD detects an error.

11. An apparatus to detect errors in a device, comprising:
a processor;
a memory module coupled to the processor; and
an Error Detection Device (EDD) coupled to the memory module and the processor, wherein said memory module sends similar information to said EDD and said processor at the same time.

12. The apparatus of claim 11, wherein the EDD uses Hamming codes to determine if the information from the memory module has errors.

13. The apparatus of claim 12, wherein the EDD uses a parity check to determine if the information from the memory module has errors.

14. The apparatus of claim 13, wherein the EDD comprises a memory storage for storing information and an address of the information if the information has errors.

15. The apparatus of claim 11, wherein the information is data, instructions, or control sequences.

16. The apparatus of claim 11, wherein the EDD couples to the processor through interrupt, reset, and abort means.

17. The apparatus of claim 11, wherein the memory module comprises:
a memory interface, wherein said memory interface couples to the processor;
a memory device coupled to the memory interface; and
a parity module coupled to the memory interface.

18. The apparatus of claim 17, wherein said memory device couples to the EDD, wherein said parity module couples to the EDD.

19. The apparatus of claim 11, further comprising:
an Input/Output (I/O) Unit coupled to the processor; and
a peripheral module coupled to the I/O unit, wherein the I/O unit couples to the EDD.

20. The apparatus of claim 19, wherein the peripheral module comprises:
an engine control unit coupled to the I/O unit;
an automatic transmission control unit coupled to the I/O unit; and
an anti-lock brake system control unit coupled to the I/O unit.

21. The apparatus of claim 19, wherein the peripheral module comprises:
a tire pressure sensor coupled to the I/O unit;
an air intake sensor coupled to the I/O unit; and
a revolution sensor coupled to the I/O unit.

22. The apparatus of claim 19, wherein the peripheral module comprises:
a hydraulic actuator coupled to the I/O unit;
a fuel injection valve actuator coupled to the I/O unit; and
a diagnosis indicator coupled to the I/O unit.

23. An apparatus to detect errors in a device, comprising:
a processor;
a memory module coupled to the processor;
an Error Detection Device (EDD) coupled to the memory module and the processor, wherein said memory module sends similar information to said EDD and said processor at the same time;
an Input/Output (I/O) unit coupled to the processor, wherein the I/O unit couples to the EDD;
a peripheral module coupled to the I/O unit; and
wherein said EDD detects errors in the information from the memory module as the device functions.
